(19) United States
(12) Patent Application Publication
(10) Pub. No.: US 2018/0075625 A1
(43) Pub. Date: Mar. 15, 2018

(54) LED PACKAGE STRUCTURE, DISPLAY APPARATUS, AND METHOD FOR COLOR DISPLAY

(71) Applicants: HISENSE ELECTRIC CO., LTD., Qingdao (CN); HISENSE USA CORPORATION, Suwanee, GA (US); HISENSE INTERNATIONAL CO., LTD., Qingdao (CN)

(72) Inventors: FULIN LI, QINGDAO (CN); ZHENGUO LIU, QINGDAO (CN)

(21) Appl. No.: 15/394,736

(22) Filed: Dec. 29, 2016

(30) Foreign Application Priority Data
Sep. 12, 2016 (CN) 201610816747.3
Sep. 12, 2016 (CN) 201610819418.4
Sep. 12, 2016 (CN) 201610819420.1
Sep. 12, 2016 (CN) 201610819484.1

(51) Int. Cl. G06T 11/00; H01L 33/34; H01L 27/15; H01L 33/48; G09G 3/20; G09G 3/32

(52) U.S. Cl. CPC G06T 11/001; H01L 33/34; H01L 27/156; G09G 2300/0452; G09G 3/2003; G09G 3/32; G09G 2320/0666; H01L 33/483

(57) ABSTRACT

The present application provides an LED package structure, a display apparatus, and a method for color display. The LED package structure of the present application includes: at least one graphene LED chip, a white-light LED structure, an LED package holder provided with an optical cup; where the at least one graphene LED chip and the white-light LED structure are packaged in the optical cup, and a plurality of adjustable wavelength points of the at least one graphene LED chip together with a white light point of the white-light LED structure form a gamut display range. The present application can improve the gamut display range of the display apparatus.

### CROSS-REFERENCE TO RELATED APPLICATIONS

This application claims the priority of Chinese patent application No. 201610819420.1, entitled “LED Package Structure and Display Apparatus”, and the priority of Chinese patent application No. 201610819484.1, entitled “LED Package Structure, Display Apparatus and Method for Color Display”, and the priority of Chinese patent application No. 201610816747.3, entitled “Light Source Assembly and Liquid Crystal Display Apparatus”, and the priority of Chinese patent application No. 201610819418.4, entitled “LED Package Structure, Display Apparatus, and Method for Color Display”, all of which are filed to the Patent Office of the People's Republic of China on Sep. 12, 2016 and are hereby incorporated by reference in their entireties.

### TECHNICAL FIELD

The present application relates to the field of display technologies, and more particularly, to an LED package structure, a display apparatus, and a method for color display.

### BACKGROUND

In the current display industry, the color mixing of three primary colors, i.e. red, green and blue is used to achieve color display. According to the principle of color mixing, the area of the triangle surrounded by the color coordinates of the three primary colors is the color range that can be realized, known as the gamut of the display apparatus. The common devices used for display include light-emitting diodes (LEDs). For all LED devices, the emission color or wavelength is determined by the emission material. Once the LED device is manufactured, the emission wavelength is fixed.

Therefore, as the emission wavelength of the LED devices is fixed, gamut limit that the display apparatus can achieve using the color mixing of three primary colors is shown in FIG. 1.

### SUMMARY

The present application provides an LED package structure, a display apparatus, and a method for color display.

The present application provides a light-emitting diode (LED) package structure comprising at least one graphene LED chip, a white-light LED structure, an LED package holder provided with an optical cup;

where the at least one graphene LED chip and the white-light LED structure are packaged in the optical cup, and a plurality of adjustable wavelength points of the at least one graphene LED chip together with a white light point of the white-light LED structure form a gamut display range.

The present application also provides a display apparatus including: a housing and a display panel, where the display panel includes a plurality of LED package structures as described in any one of the above, the plurality of LED package structures being arranged in an array;

where the display panel is arranged in the housing, and the LED package structures are arranged on a printed circuit board (PCB) of the display apparatus.

The present application also provides a method for color display of a display apparatus using a light-emitting diode (LED) package structure, where the LED package structure includes the structure as described in any one of the above, the method includes:

determining the plurality of adjustable wavelength points of the at least one graphene LED chip;

forming a gamut display range of the display apparatus according to a plurality of regions formed by the plurality of adjustable wavelength points and the white light point of the white-light LED structure.

### BRIEF DESCRIPTION OF DRAWINGS

FIG. 1 is a schematic diagram of a gamut limit in the related art provided by the present application;

FIG. 2 is schematic structural diagram 1 of an LED package structure provided by an embodiment of the present application;

FIG. 3 is schematic diagram 1 of a color display principle provided by an embodiment of the present application;

FIG. 4 is schematic diagram 2 of a color display principle provided by an embodiment of the present application;

FIG. 5 is schematic structural diagram 2 of an LED package structure provided by an embodiment of the present application;

FIG. 6 is schematic structural diagram 3 of an LED package structure provided by an embodiment of the present application;

FIG. 7 is schematic structural diagram 4 of an LED package structure provided by an embodiment of the present application;

FIG. 8 is schematic structural diagram 5 of an LED package structure provided by an embodiment of the present application;

FIG. 9 is schematic structural diagram 6 of an LED package structure provided by an embodiment of the present application;

FIG. 10 is schematic structural diagram 7 of an LED package structure provided by an embodiment of the present application;

FIG. 11 is schematic structural diagram 8 of an LED package structure provided by an embodiment of the present application;

FIG. 12 is schematic diagram 3 of a color display principle provided by an embodiment of the present application;

FIG. 13 is schematic structural diagram 9 of an LED package structure provided by an embodiment of the present application;

FIG. 14 is schematic structural diagram 10 of an LED package structure provided by an embodiment of the present application;

FIG. 15 is schematic structural diagram 11 of an LED package structure provided by an embodiment of the present application;

FIG. 16 is schematic structural diagram 12 of an LED package structure provided by an embodiment of the present application;

FIG. 17 is schematic structural diagram 13 of an LED package structure provided by an embodiment of the present application;

FIG. 18 is schematic structural diagram 14 of an LED package structure provided by an embodiment of the present application;

FIG. 19 is schematic structural diagram 15 of an LED package structure provided by an embodiment of the present application;

FIG. 20 is schematic structural diagram 16 of an LED package structure provided by an embodiment of the present application;

FIG. 21 is schematic structural diagram 17 of an LED package structure provided by an embodiment of the present application;

FIG. 22 is schematic diagram 4 of a color display principle provided by an embodiment of the present application;

FIG. 23 is schematic structural diagram 18 of an LED package structure provided by an embodiment of the present application;

FIG. 24 is schematic structural diagram 19 of an LED package structure provided by an embodiment of the present application;

FIG. 25 is schematic structural diagram 20 of an LED package structure provided by an embodiment of the present application;

FIG. 26 is schematic structural diagram 21 of an LED package structure provided by an embodiment of the present application;

FIG. 27 is schematic structural diagram 22 of an LED package structure provided by an embodiment of the present application;

FIG. 28 is schematic structural diagram 23 of an LED package structure provided by an embodiment of the present application;

FIG. 29 is a schematic structural diagram of a display apparatus provided by an embodiment of the present application; and

FIG. 30 is a flowchart of a method for color display of a display apparatus using an LED package structure provided by an embodiment of the present application.

### DESCRIPTION OF REFERENCE SIGNS

100: LED package structure;
10: graphene LED chip;
11: white-light LED structure;
12: optical cup;
13: LED package holder;
14: first LED chip;
15: first optical cup;
16: second optical cup;
17: second LED chip;
101: red-light chip;
102: blue-light chip;
103: yellow fluorescent powder;
104: red fluorescent powder;
105: green fluorescent powder;
111: blue-light LED chip;
112: first mixed fluorescent material;
122: yellow fluorescent material;
131: ultraviolet LED chip;
132: second mixed fluorescent material;
200: display apparatus;
20: housing;
21: display panel;
22: PCB.

### DETAILED DESCRIPTION

The LED package structure according to embodiments of the present application can be applied to any terminal device having a display apparatus, and is applicable to, for example, a television, a mobile phone, a tablet computer, a personal digital assistant (PDA), a point of sales (POS), an auto PC, and other devices that have a display screen, and the embodiments of the present application are not limited to the form of the terminal device to which the present application is applied.

It should be understood that, although the terms first, second, third, etc. may be used in the embodiments of the present application to describe XXX, such XXX should not be limited to these terms. These terms are only used to distinguish XXX from each other. For example, a first XXX may also be referred to as a second XXX without departing from the scope of embodiments of the present application, and similarly, a second XXX may also be referred to as a first XXX.

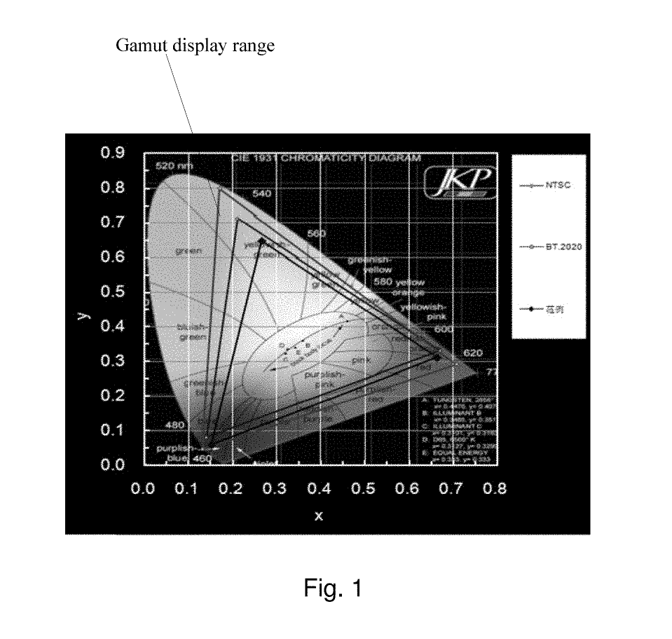

When an existing display device is performing color display, the principle of color mixing of three primary colors is used and the gamut limit achieved by the use of color mixing of three primary colors is shown in FIG. 1. The gamut limit is the area of the largest triangle enclosed by red, green and blue falling on a spectral line of a horseshoe chart. However, the color that the human eye can feel is the entire horseshoe chart, while the range outside the triangle cannot be displayed by the display device. Therefore, the gamut display range of the related art is relatively narrow and cannot meet the requirements of users for display.

The LED package structure and the display apparatus provided by embodiments of the present application are intended to solve the above-mentioned technical problems of the related art so as to improve the gamut display range of the display apparatus.

Hereinafter, the technical solutions of the present application will be described in detail with reference to specific embodiments. The following specific embodiments may be combined with one another, and the same or similar concepts or processes may not be repeated in certain embodiments.

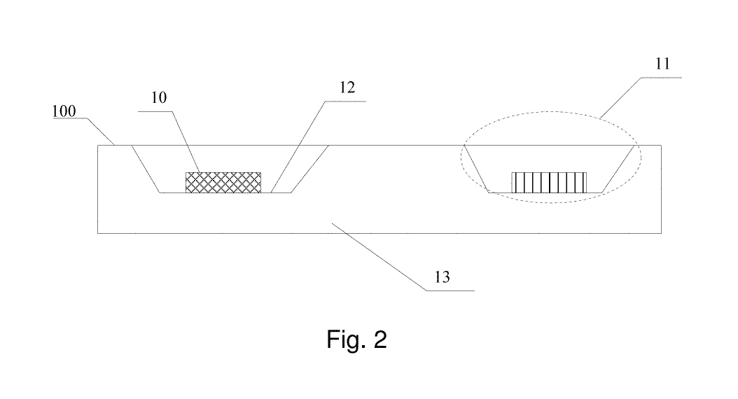

FIG. 2 is a schematic structural diagram of an LED package structure provided by an embodiment of the present application; as shown in FIG. 2, the LED package structure 100 includes: at least one graphene LED chip 10, a white-light LED structure 11, and an LED package holder 13 provided with an optical cup 12.

The at least one graphene LED chip 10, the white-light LED structure 11 are packaged in the optical cup 12, and a plurality of adjustable wavelength points of the at least one graphene LED chip 10 together with a white light point of the white-light LED structure 11 form a gamut display range.

Before introducing the solution of the embodiments of the present application, the characteristics of the graphene LED chip 10 employed in the embodiments of the present application will be first described.

The graphene LED chip 10 mainly uses a semi-reduced graphene oxide (srGO) material, and the srGO material can be obtained from the interface of oxidized graphene and reduced graphene by a laser direct writing technology. The srGO material has the high conductivity of graphene and the wide bandgap characteristics of oxidized graphene. By structuring the in-plane grid structure of the graphene LED chip 10 and applying a voltage to the grid of the graphene LED chip 10, the Fermi level of the srGO material can be adjusted such that the emission wavelength of the graphene LED chip 10 is adjusted in real time.

That is, the graphene LED chip 10 used in the embodiments of the present application can adjust the center emission wavelength of the graphene LED in real time by adjusting the voltage applied to the grid, and by applying different grid voltages, the emission wavelength of the graphene LED chip 10 can be continuously adjustable in the range of 450 nm˜750 nm, substantially covering the entire range of visible light. Each graphene LED chip 10 may has at least one adjustable wavelength point. One wavelength point of the graphene LED chip 10 may correspond to output light of one color. The total number of adjustable wavelength points of at least one graphene LED chip 10 may be the number of adjustable wavelength points required for the LED package structure. The number of adjustable wavelength points required for the LED package structure 100 may be greater than or equal to three.

The number of the graphene LED chips 10 may be one, or may be more than one. The number of the graphene LED chips 10 is not limited in the embodiments of the present application. It should be noted that, one graphene LED chip is included in the LED package structure which is shown in FIG. 2, and the LED package structure shown in FIG. 2 merely illustrates the LED package structure by way of example, rather than limiting the LED package structure.

When the LED package structure includes one graphene LED chip 10, the one graphene LED chip 10 has a plurality of adjustable wavelength points in the time domain in sequence. The time interval corresponding to adjacent adjustable wavelength points is within a preset time range. In this LED package structure, corresponding wavelength points can be obtained by applying a voltage of a corresponding wavelength point at a plurality of time points continuous in the time domain, respectively, and the time interval corresponding to the adjacent adjustable wavelength points is within a preset time range. For the LED package structure 100 including one graphene LED chip 10, a plurality of adjustable wavelength points of the graphene LED chip 10 may be realized in the time domain.

Each graphene LED chip 10 has at least one adjustable wavelength point in the time domain when the LED package structure includes a plurality of graphene LED chips 10, and different graphene LED chips 10 have different adjustable wavelength points at the same moment. In such an LED package structure, a plurality of adjustable wavelength points of the graphene LED chips 10 can be realized in a manner of combining time domain and space.

For example, it is assumed that the number of adjustable wavelength points required for the LED package structure 100 may be five.

When the number of graphene LED chips 10 is 2, one graphene LED chip 10 may be enabled to have 2 adjustable wavelength points in the time domain and another graphene LED chip 10 may be enabled to have the remaining 3 wavelength points in the time domain.

When the number of graphene LED chips 10 is 5, each graphene LED chip 10 may be enabled to have one of the 5 adjustable wavelength points respectively, and different graphene LED chips 10 have different adjustable wavelength points.

The white-light LED structure 11 may emit white light to adjust the saturation of the output light color of the graphene LED chip 10. The white-light LED structure 11 may include: a primary color light LED chip, and a fluorescent material of other color except this primary color in three primary colors, where primary color light emitted by the primary color LED chip can excite the fluorescent material of other color to emit white light. The white-light LED structure 11 may also include: an ultraviolet LED chip, and three primary color fluorescent materials.

The LED package holder 13 is made of highly reflective, illumination aging-resistant and highly malleable material, such as epoxy molding compound (EMC) material, which can perform encapsulation and protection on the graphene LED chip 10 and white-light LED structure 11 and other components located in the optical cup 12. The optical cup 12 on the LED package holder 13 can improve the forward luminous efficiency.

The number of the optical cups 12 on the LED package holder 13 may be one or more, and the number of the optical cups 12 is not limited by the embodiments of the present application. The number of the optical cups 12 shown in FIG. 2 takes 2 as an example, to which the application is not limited.

The driving of each of the graphene LED chips 10 and the white-light LED structure 11 is controlled respectively and independently.

Since the at least one graphene LED chip 10 has a plurality of adjustable wavelength points and the white-light LED structure 11 has a fixed white light point, the first wavelength point and the second wavelength point in the plurality of adjustable wavelength points of the at least one graphene LED chip 10 can form a display area with the white light point of the white-light LED structure 11, and the structure of the display area is a triangle. In this way, the plurality of adjustable wavelength points of at least one graphene LED chip 10 and the white light point of the white-light LED structure 11 may form a plurality of triangles which occupy an area in the horseshoe chart larger than that of the largest triangle in FIG. 1, and the reasons are as follows:

In the related art, the gamut range which the display device can display is the area occupied on the horseshoe chart by the largest triangle in FIG. 1, where the largest triangle in FIG. 1 is formed by the color mixing of red, green and blue, three vertices of the largest triangle are the red light point, blue light point and green light point. The LED package structure 100 of the present application includes at least one graphene LED chip 10 and the white-light LED structure 11 having the fixed white light point. One adjustable wavelength point of the graphene LED chip 10 in the horseshoe chart may correspond to one vertex of a triangle, and two different adjustable wavelength points may correspond to two vertices of a triangle, while the white light point of the white-light LED structure 11 may correspond to the other vertex of the triangle. The two vertices of the triangle corresponding to the two adjustable wavelength points can be any two vertices of the largest triangle in FIG. 1. In this way, only by adjusting a plurality of adjustable wavelength points of the graphene LED chip 10, can a plurality of triangles of different areas be enclosed, and when the wavelength points of the graphene LED chip 10 are adjusted, make sure that the areas of the plurality of enclosed triangles on the horseshoe chart are larger than the area of the largest triangle in FIG. 1.

In the following, detailed description will be made respectively by different numbers of adjustable wavelength points of at least one graphene LED chip 10 with respect to the color display principle.

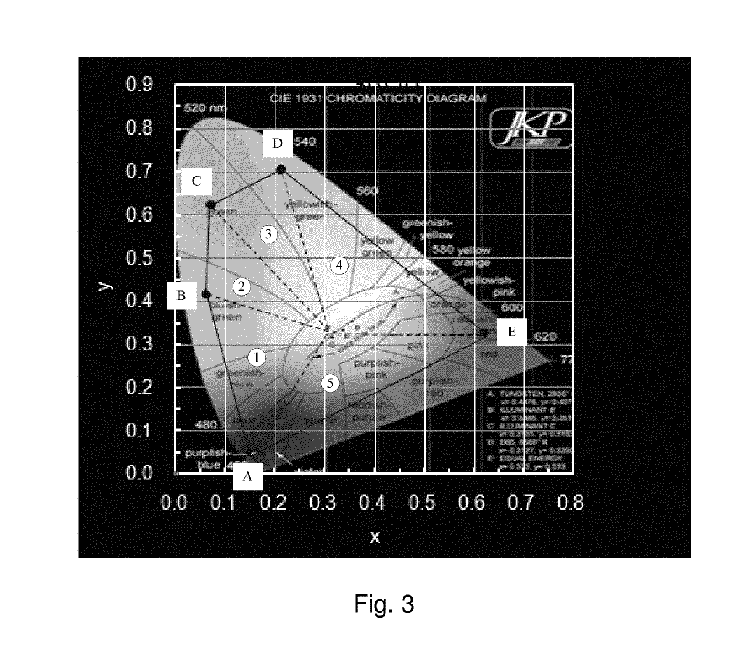

For example, FIG. 3 is schematic diagram 1 of a color display principle provided by an embodiment of the present application. In FIG. 3, the vertex A, the vertex B, the vertex C, the vertex D, and the vertex E are the set five wavelength points of the graphene LED chip 10 of which the emission wavelength is adjustable, respectively, and the one located at the center point may be the white light point of the white-light LED structure 11. Setting five wavelength points by the graphene LED chip 10 is taken as an example. The white light point in the center and the vertex A, the vertex B, the vertex C, the vertex D and the vertex E, totally 6 points, can form totally 5 color display areas, namely, area \textcircled{1}, area \textcircled{2}, area \textcircled{3}, area \textcircled{4} and area \textcircled{5}. When two wavelength points in the plurality of adjustable wavelength points of at least one graphene LED chip 10 in the LED package structure 100 correspond to the vertex A and the vertex B respectively, the vertex A, the vertex B and the white light point can be mixed to form tall the colors in area \textcircled{1}, allowing the display apparatus to display all the colors within area \textcircled{1}. When two wavelength points in the plurality of adjustable wavelength points of at least one graphene LED chip 10 in the LED package structure 100 correspond to the vertex B and the vertex C respectively, the vertex B, the vertex C and the white light point can be mixed to form all the colors in area \textcircled{2}, allowing the display apparatus to display all the colors within area \textcircled{2}. When two wavelength points in the plurality of adjustable wavelength points of at least one graphene LED chip 10 in the LED package structure 100 correspond to the vertex C and the vertex D respectively, the vertex C, the vertex D and the white light point can be mixed to form all the colors in area \textcircled{3}, allowing the display apparatus to display all the colors within area \textcircled{3}. When two wavelength points in the plurality of adjustable wavelength points of at least one graphene LED chip 10 in the LED package structure 100 correspond to the vertex D and the vertex E respectively, the vertex D, the vertex E and the white light point can be mixed to form all the colors in area \textcircled{4}, allowing the display apparatus to display all the colors within area \textcircled{4}. When two wavelength points in the plurality of adjustable wavelength points of at least one graphene LED chip 10 in the LED package structure 100 correspond to the vertex A and the vertex E respectively, the vertex A, the vertex E and the white light point can be mixed to form all the colors in area \textcircled{5}, allowing the display apparatus to display all the colors within area \textcircled{5}. Where, the area \textcircled{5} is a complementary color area without a corresponding wavelength, which needs to be formed by color mixing of the vertex A, the vertex E and the white light point.

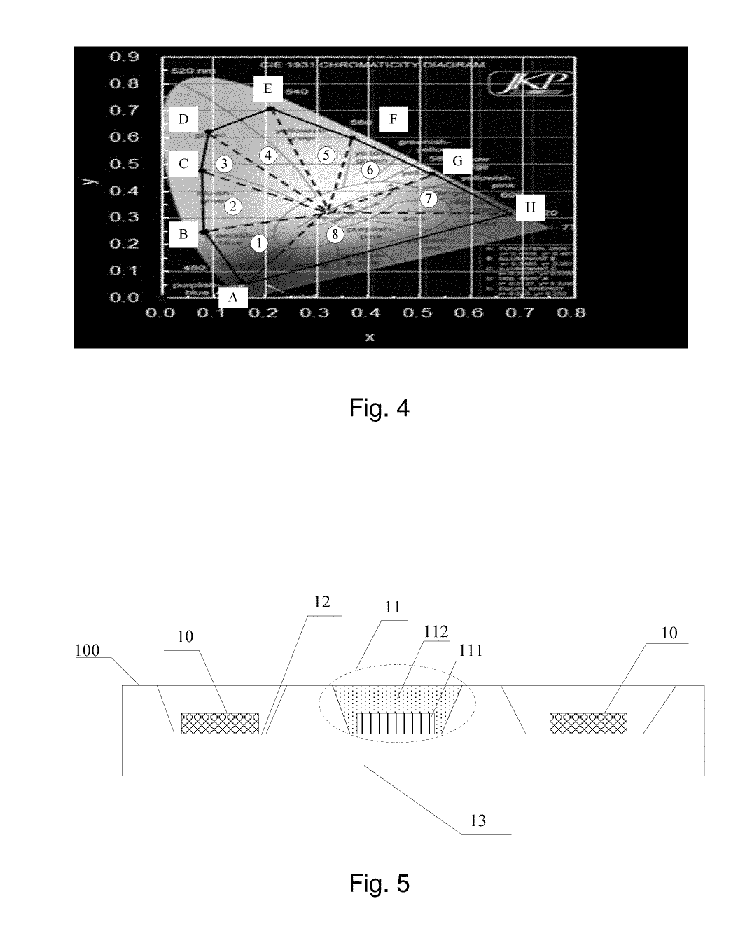

FIG. 4 is schematic diagram 2 of a color display principle provided by the present application In FIG. 4, the vertex A, the vertex B, the vertex C, the vertex D, the vertex E, the vertex F, the vertex G and the vertex H are the set eight wavelength points of the graphene LED chip 10 of which the emission wavelength is adjustable, respectively, and the one located at the center point may be the white light point of the white-light LED structure 11. Setting eight wavelength points by the graphene LED chip 10 is taken as an example. The white light point in the center and the vertex A, the vertex B, the vertex C, the vertex D and the vertex E the vertex F, the vertex G and the vertex H, totally 9 points, can form totally 8 color display areas, namely, area \textcircled{1}, area \textcircled{2}, area \textcircled{3}, area \textcircled{4} and area \textcircled{5}, area \textcircled{6}, area \textcircled{7}, area \textcircled{8}. When two wavelength points in the plurality of adjustable wavelength points of at least one graphene LED chip 10 in the LED package structure 100 correspond to the vertex A and the vertex B respectively, the vertex A, the vertex B and the white light point can be mixed to form all the colors in area \textcircled{1}, allowing the display apparatus to display all the colors within area \textcircled{1}. When two wavelength points in the plurality of adjustable wavelength points of at least one graphene LED chip 10 in the LED package structure 100 correspond to the vertex B and the vertex C respectively, the vertex B, the vertex C and the white light point can be mixed to form all the colors in area \textcircled{2}, allowing the display apparatus to display all the colors within area \textcircled{2}. When two wavelength points in the plurality of adjustable wavelength points of at least one graphene LED chip 10 in the LED package structure 100 correspond to the vertex C and the vertex D respectively, the vertex C, the vertex D and the white light point can be mixed to form all the colors in area \textcircled{3}, allowing the display apparatus to display all the colors within area \textcircled{3}. When two wavelength points in the plurality of adjustable wavelength points of at least one graphene LED chip 10 in the LED package structure 100 correspond to the vertex D and the vertex E respectively, the vertex D, the vertex E and the white light point can be mixed to form all the colors in area \textcircled{4}, allowing the display apparatus to display all the colors within area \textcircled{4}. When two wavelength points in the plurality of adjustable wavelength points of at least one graphene LED chip 10 in the LED package structure 100 correspond to the vertex E and the vertex F respectively, the vertex E, the vertex F and the white light point can be mixed to form all the colors in area \textcircled{5}, allowing the display apparatus to display all the colors within area \textcircled{5}. When two wavelength points in the plurality of adjustable wavelength points of at least one graphene LED chip 10 in the LED package structure 100 correspond to the vertex F and the vertex G respectively, the vertex F, the vertex G and the white light point can be mixed to form all the colors in area \textcircled{6}, allowing the display apparatus to display all the colors within area \textcircled{6}. When two wavelength points in the plurality of adjustable wavelength points of at least one graphene LED chip 10 in the LED package structure 100 correspond to the vertex G and the vertex H respectively, the vertex G, the vertex H and the white light point can be mixed to form all the colors in area \textcircled{7}, allowing the display apparatus to display all the colors within area \textcircled{7}. When two wavelength points in the plurality of adjustable wavelength points of at least one graphene LED chip 10 in the LED package structure 100 correspond to the vertex A and the vertex H respectively, the vertex A, the vertex H and the white light point can be mixed to form all the colors in area \textcircled{8}, allowing the display apparatus to display all the colors within area \textcircled{8}. Where, the area \textcircled{8} is a complementary color area without a corresponding wavelength, which needs to be formed by color mixing of the vertex A, the vertex H and the white light point.

The LED package structure provided by the embodiment of the application includes at least one graphene LED chip, the white-light LED structure, the LED package holder provided with the optical cup; where the at least one graphene LED chip and the white-light LED structure are packaged in the optical cup, and the plurality of adjustable wavelength points of the at least one graphene LED chip together with the white light point of the white-light LED structure form the gamut display range. Since the graphene LED chip has an adjustable wavelength point, a plurality of adjustable wavelength points can be obtained by adjusting the grid voltage of the at least one graphene LED chip, and the gamut display range formed according to the plurality of adjustable wavelength points and the white light point of the white-light LED structure can be improved, thereby gamut display range of the display apparatus can be greatly improved.

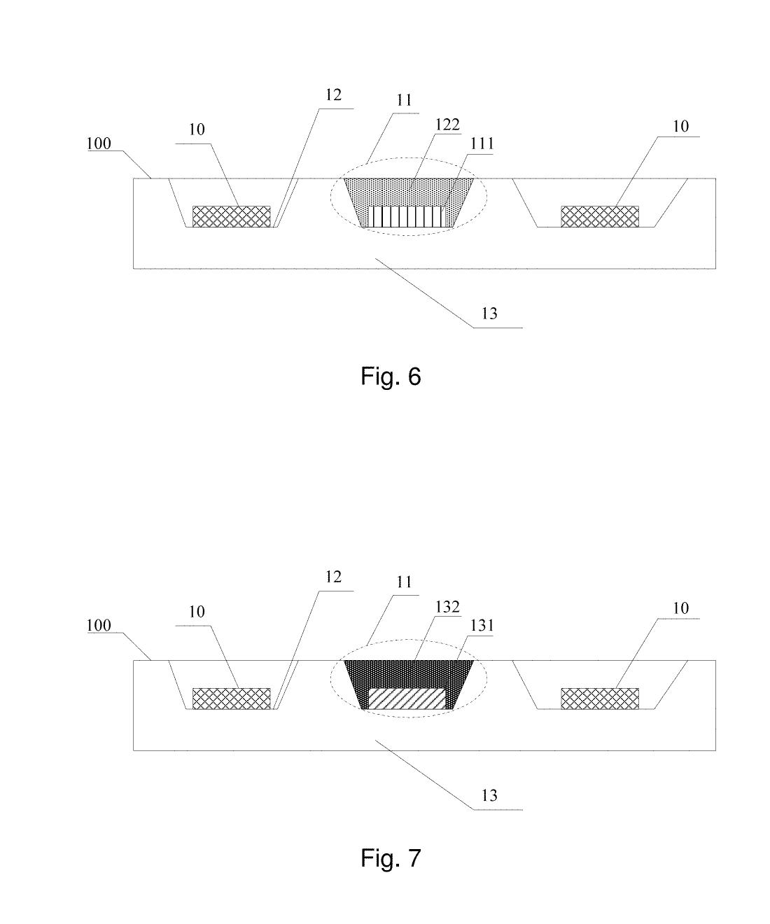

FIG. 5 is schematic structural diagram 2 of an LED package structure provided by an embodiment of the present application. FIG. 6 is schematic structural diagram 3 of an LED package structure provided by an embodiment of the present application. FIG. 7 is a schematic structural diagram 4 of an LED package structure provided by an embodiment of the present application.

In the LED package structure 100 of the present application, the LED package holder 13 may include a first optical cup (e.g. the optical cup 12 in the middle shown in FIG. 5) and at least one third optical cup (e.g. the optical cups 12 on the left and right shown in FIG. 5), where the white-light LED structure 11 is packaged in the first optical cup; at least one graphene LED chip 10 is packaged in at least one third optical cup.

In embodiments shown in FIGS. 5-7, the LED package holder 13 related to the LED package structure 100 may include three optical cups 12. The LED package structure 100 includes two graphene LED chips 10. Each graphene LED chip 10 is packaged in one optical cup 12 (i.e. the third optical cup), and the white-light LED structure 11 is packaged in one optical cup 12 (i.e. the first optical cup).

With reference to FIG. 5, the above-mentioned white-light LED structure 11 may include: a blue-light LED chip 111, a first mixed fluorescent material 112 composed of a red fluorescent material and a green fluorescent material.

With reference to FIG. 6, the above-mentioned white-light LED structure 11 may include: a blue-light LED chip 111 and a yellow fluorescent material.

With reference to FIG. 7, the above-mentioned white-light LED structure 11 may include: an ultraviolet LED chip 131, a second mixed fluorescent material 132 composed of a blue fluorescent material, a red fluorescent material and a green fluorescent material.

It should be noted that FIGS. 5-7 illustrate the examples where 2 graphene LED chips 10 are included. However, the LED package structure 100 of the present application may also include graphene LED chips 10 of other quantities. In FIGS. 5-7, positions of the above-mentioned graphene LED chip 10 and the white-light LED structure 11 in the LED package holder 13 are arbitrarily interchangeable. For example, it is also possible to arrange the first graphene LED chip 10 in the first optical cup 12 on the left, the another graphene LED chip 10 in the optical cup 12 positioned in the middle, and the white-light LED structure 11 in the first optical cup 12 on the right. Of course, it can also be arranged in other interchange manner, as long as one chip is packaged in one optical cup 12. The LED package structure shown in FIGS. 5-7 greatly improves the luminous efficiency of each LED chip by the one-to-one correspondence between the optical cup and the LED chip.

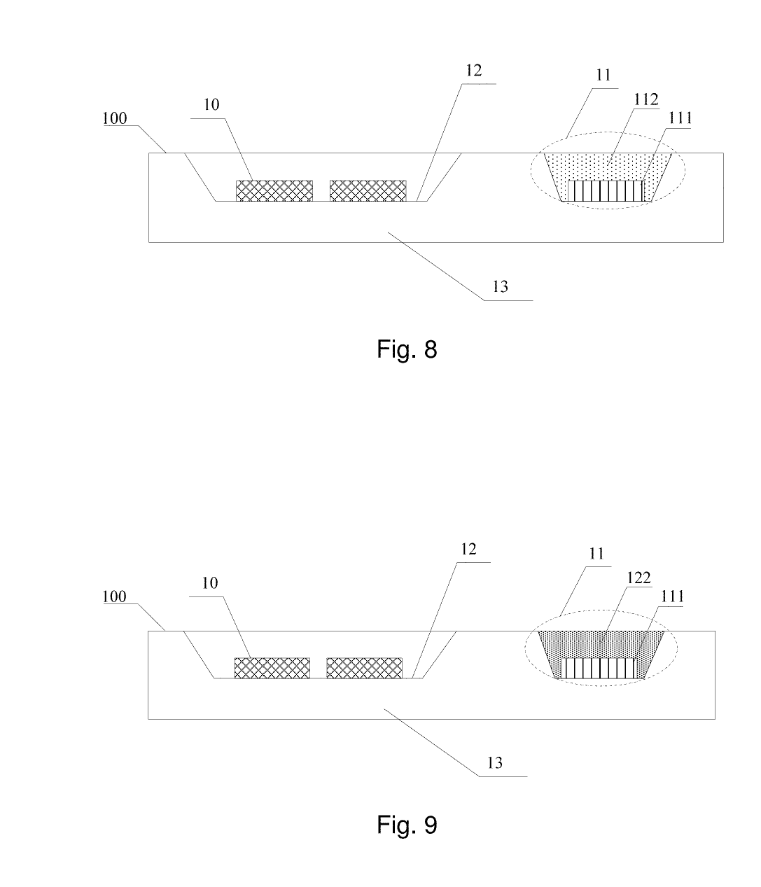

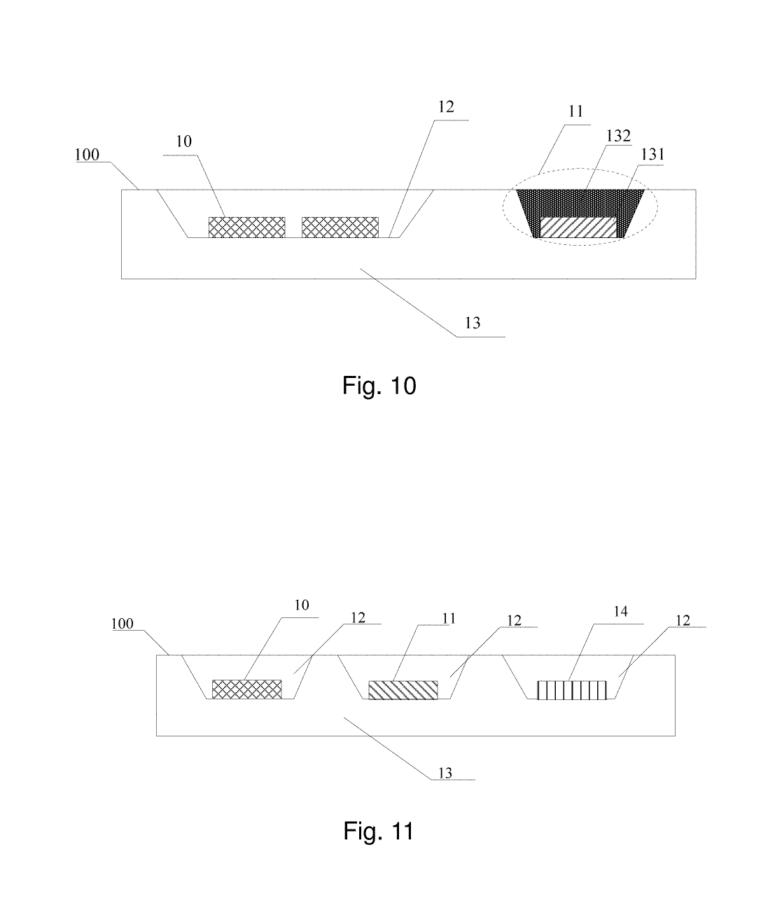

FIG. 8 is schematic structural diagram 5 of an LED package structure provided by an embodiment of the present application. FIG. 9 is schematic structural diagram 6 of an LED package structure provided by an embodiment of the present application. FIG. 10 is schematic structural diagram 7 of an LED package structure provided by an embodiment of the present application.

In the embodiment shown in FIGS. 8-10, the LED package holder 13 related to the LED package structure 100 may include two optical cups 12. The LED package structure 100 includes two graphene LED chips 10. The two graphene LED chips 10 are jointly packaged in one optical cup, and the white-light LED structure 11 is packaged in another one optical cup 12.

With reference to FIG. 8, the above-mentioned white-light LED structure 11 may include: a blue-light LED chip 111, a first mixed fluorescent material 112 composed of a red fluorescent material and a green fluorescent material.

With reference to FIG. 9, the above-mentioned white-light LED structure 11 may include: a blue-light LED chip 121 and a yellow fluorescent material.

With reference to FIG. 10, the above-mentioned white-light LED structure 11 may include: an ultraviolet LED chip 131, a second mixed fluorescent material 132 composed of a blue fluorescent material, a red fluorescent material and a green fluorescent material.

It should be noted that FIGS. 8-10 illustrate the examples where 2 graphene LED chips 10 are included. However, the LED package structure 100 of the present application may also include graphene LED chips 10 of other quantities. In FIGS. 8-10, positions of the above-mentioned graphene LED chip 10 and the white-light LED structure 11 in the LED package holder 13 are arbitrarily interchangeable. For example, it is also possible to arrange the two graphene LED chips 10 in FIG. 8 in the first optical cup 12 on the right and the white-light LED structure 11 in the first optical cup 12 on the left. Of course, it can also be arranged in other interchange manner, as long as the plurality of graphene LED chips 10 are packaged in one optical cup 12.

In the LED package structure shown in FIGS. 8-10, a plurality of graphene LED chips are packaged jointly in one optical cup, which greatly improves the packaging efficiency of the LED package structure, and reduces the packaging complexity and the packaging cost.

FIG. 11 is schematic structural diagram 8 of an LED package structure provided by an embodiment of the present application. On the basis of any of the embodiments described above, the LED package structure may further include a first LED chip 14 for emitting primary color light, where the first LED chip 14 is packaged in the optical cup 12; the plurality of adjustable wavelength points of the at least one graphene LED chip 10 form a gamut display range together with the white light point of the white-light LED structure 11 and a wavelength point of the first LED chip 14, respectively.

The first LED chip 14 has a fixed wavelength point. The first LED chip 14 may be a red light chip emitting red light or a blue light chip emitting blue light.

As the above-mentioned graphene LED chip 10 has a plurality of adjustable wavelength points, the white-light LED structure 11 has the white light point, and the first LED chip 14 has the fixed wavelength point, each of the above-mentioned wavelength points of the graphene LED chip 10 can form a display area together with the white light point and the wavelength point of the above-mentioned first LED chip 14. The structure of the display area may include a radial area in which the white light point is positioned in the center, and the plurality of adjustable wavelength points of the graphene LED chip 10 and the wavelength point of the first LED chip 14 serve as radiant points. And on the basis of the radial area, color mixing may be further performed on one adjustable wavelength point of the graphene LED chip 10 with the wavelength point of the first LED chip 14, which forms a complementary color area. The radial area and the complementary color area jointly form the gamut display range of the embodiment of the present application. Since the wavelength points of the graphene LED chip 10 are adjustable, it is possible to ensure that the gamut display range of the embodiment of the present application is larger than the area of the largest triangle in FIG. 1 by controlling the position of the wavelength points of the graphene LED chip 10 on the horseshoe chart. The reason is as follows:

In the related art, the gamut range which the display device can display is the area occupied on the horseshoe chart by the largest triangle in FIG. 1, where the largest triangle in FIG. 1 is formed by the color mixing of red, green and blue, three vertices of the largest triangle are the red light point, blue light point and green light point. The LED package structure 100 of the present application includes the white-light LED structure 11 and the first LED chip 14, the two having fixed wavelengths, and the graphene LED chip 10 which is wavelength adjustable. The wavelength point of the first LED chip 14 in the horseshoe chart and two adjustable wavelength points of the graphene LED chip 10 may be controlled so that the wavelength point of the first LED chip 14 and the two adjustable wavelength points of the graphene LED chip 10 correspond to the three vertices of the largest triangle in FIG. 1, namely, to make the area of the triangle enclosed by the wavelength point of the first LED chip 14 and the two adjustable wavelength points of the graphene LED chip 10 equal to the area of the largest triangle in FIG. 1. In this way, it is only needed to adjust the other plurality of wavelength points of the graphene LED chip 10 accordingly such that the gamut display range of the embodiment in the present application is larger than that of the related art.

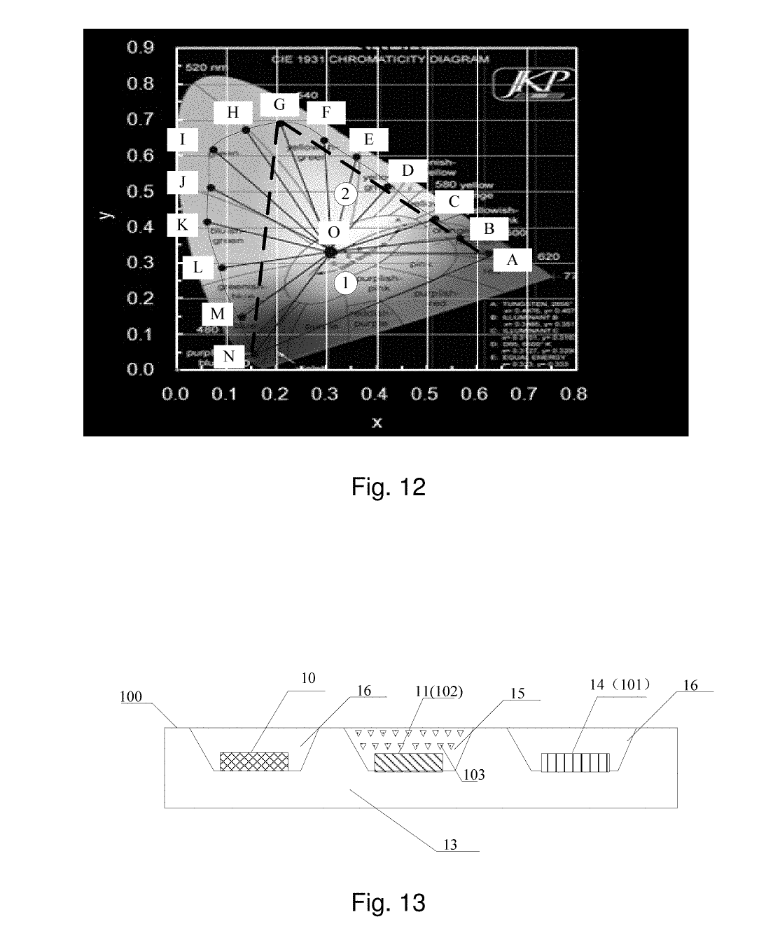

In order to describe the gamut display range of the embodiment in the present application more clearly, an example is given here: with reference to the schematic diagram 3 of a color display principle illustrated by FIG. 12, in FIG. 12, assuming that the first LED chip 14 is a red light chip capable of emitting red light, and point A (i.e., the red wavelength point) is emitted by the red light chip 101 separately (of course, the point A can also be emitted by the graphene LED chip 10 meanwhile the red light chip 101 is turned off, or the red light chip 101 and the graphene LED chip 10 are jointly turned on and emit the point), and adjustable wavelength points of the graphene LED chip 10 in FIG. 12 include points from B to N, the white light point of the white-light LED structure 11 is the point O, then it can be seen from FIG. 12 that the gamut display range of the LED package structure 100 is a radial area formed jointly by the point O serving as the center point, each of the adjustable wavelength points of the graphene LED chip 10 and the red light point serving as radiant points, and a complementary color area \textcircled{1} formed by mixing the point A and the point N, where the sum of the areas of envelope areas formed by the radial area and the complementary color area \textcircled{1} is the gamut display range that the embodiment of the present application can offer. As can be seen from FIG. 12, the triangular area formed by the above-mentioned points A, G and N equals to the area of the largest triangle in FIG. 1, but the area of the entire envelope area of FIG. 12 is larger than the area of the triangle, therefore the LED package structure 100 provided by the embodiments of the present application greatly increases the gamut display range of the display apparatus.

It should be noted that, the reason why the above-mentioned adjustable wavelength points of the graphene LED chip 10 can get away from the white light point located in the center and be located outside the triangle formed by the point A, G and N is due to the characteristics of a graphene LED; in addition, the white light point emitted by the white-light LED structure 11 in the present application is mainly for connecting a line with any one of the adjustable wavelength points of the graphene LED chip 10. All the colors on the line can be displayed by the display apparatus. Then, with the adjustment of the wavelength points of the graphene LED chip 10, i.e., with the discrete change of the wavelength points, the color on the line of the white light point with each adjustable wavelength point can be displayed so as to form the above-mentioned radial area.

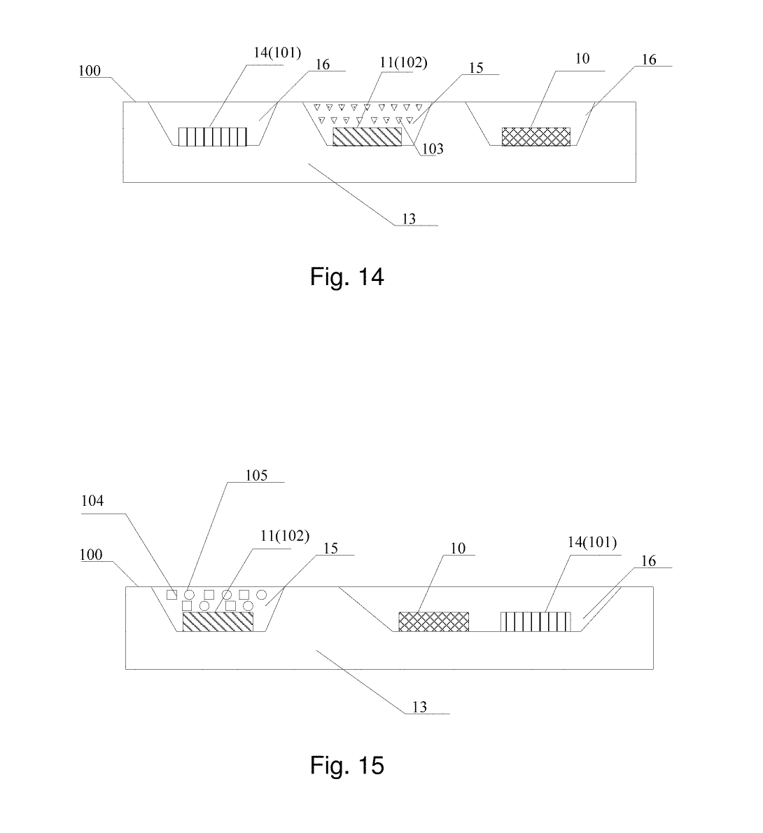

FIG. 13 is schematic structural diagram 9 of an LED package structure provided by an embodiment of the present application. FIG. 14 is schematic structural diagram 10 of an LED package structure provided by an embodiment of the present application.

In the embodiments shown in FIGS. 13-14, the LED package holder 13 includes a first optical cup 15 and at least one second optical cup 16, where the white-light LED structure 11 is packaged in the first optical cup 15; at least one graphene LED chip 10 and the first LED chip 14 are packaged in at least one second optical cup 16.

The first LED chip 14 is a red light chip 101. The LED package holder 13 related to the LED package structure 100 may include three optical cups: one first optical cup 15, two second optical cups 16. The white-light LED structure 11 is packaged in the first optical cup 15, and the graphene LED chip 10 and the first LED chip 14 (i.e., the red light chip 101) are arranged in one second optical cup 16, respectively and correspondingly. The positions of the above-mentioned first LED chip 14 and the graphene LED chip 10 can be arbitrarily interchanged to form the embodiments shown in FIGS. 13 and 14, as long as the white-light LED structure 11 is individually packaged in the first optical cup 15.

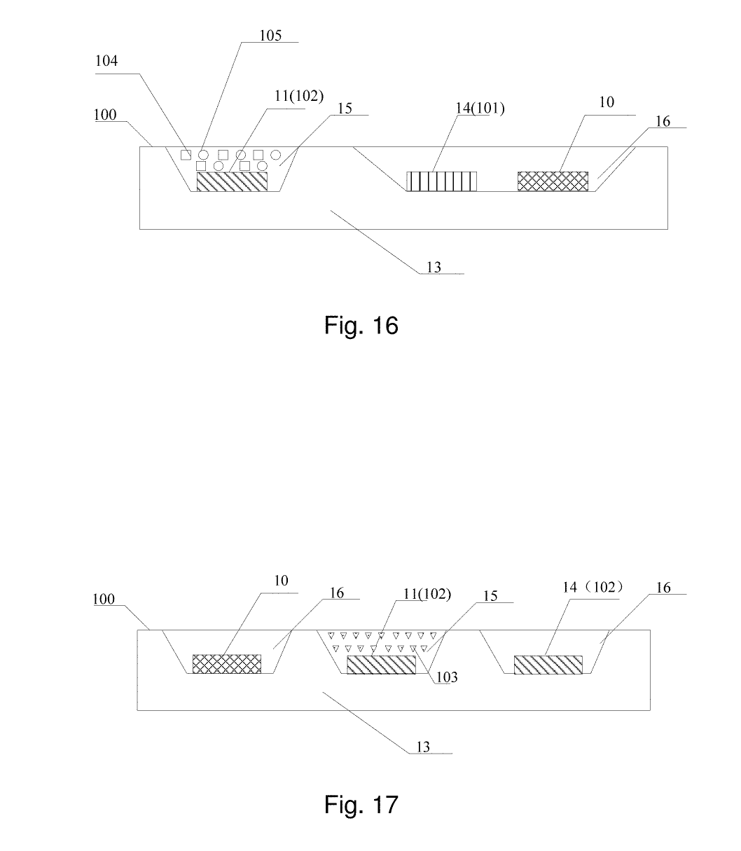

FIG. 15 is schematic structural diagram 11 of an LED package structure provided by an embodiment of the present application. FIG. 16 is schematic structural diagram 12 of an LED package structure provided by an embodiment of the present application.

In the embodiments shown in FIGS. 15 to 16, the first LED chip 14 described above is a red light chip 101, and the LED package holder 13 related to the LED package structure 100 may include a first optical cup 15 and a second optical glass 16, i.e. two optical cups, and the graphene LED chip 10 and the first LED chip 14 are arranged in one second optical cup 16 jointly. The positions of the above-mentioned first LED chip 14 and the graphene LED chip 10 in the one second optical cup 16 can be arbitrarily interchanged to form the embodiments shown in FIGS. 15 and 16, as long as the white-light LED structure 11 is individually packaged in the first optical cup 15.

In the embodiments shown in FIGS. 13 to 16, the display principle of the complementary color area is shown in FIG. 12, which includes two complementary color areas, that is respectively, area \textcircled{1} (composed of points A, 0 and N) and area \textcircled{2}(composed of points A, G and O). As for the display of area \textcircled{1}, point N (blue light point) is displayed by the graphene LED chip 10 with adjustable wavelength, point A (red light point) is displayed by the red light chip 101, and point O (white light point) is displayed by the white-light LED structure 11, so that the triangle enclosed by point A, point N and point O can be displayed to cover the entire complementary color area \textcircled{1}; When other colors are displayed (e.g., assuming that the display of green is desired), the graphene LED chip 10 can adjust the display hue, the white-light LED structure 11 can adjust the saturation, and the red light chip 101 is in the off state. As for the display of area \textcircled{2}, point G (green light point) is displayed by the graphene LED chip 10 with adjustable wavelength, point A (red light point) is displayed by the red light chip 101, and point O (white light point) is displayed by the white-light LED structure 11, so that the triangle enclosed by point A, point G and point O can be displayed to cover the entire complementary color area \textcircled{2}.

In the embodiments shown in FIGS. 13 to 16, the above-described white-light LED structure 11 may include a blue light chip 102 for emitting blue light and yellow fluorescent powder 103 packaged in silica gel on the surface of the blue light chip 102; or, it may include a blue light chip 102 for emitting blue light and green fluorescent powder 105 and red fluorescent powder 104 that are packaged in the silica gel on the surface of the blue light chip 102. It should be noted that, the white-light LED structure shown in FIGS. 13 and 14 is composed of the blue light chip 102 and yellow fluorescent powder 103 packaged in silica gel on the surface of the blue light chip 102, and the white-light LED structure shown in FIGS. 15 and 16 is composed of the blue light chip 102 and the green fluorescent powder 105 and red fluorescent powder 104 that are packaged in silica gel on the surface of the blue light chip 102, which only serve as examples, that is to say, the white-light LED structure shown in FIGS. 13 and 14 may also be composed of the blue light chip 102 and the green fluorescent powder 105 and red fluorescent powder 104 that are packaged in the silica gel on the surface of the blue light chip 102, and the white-light LED structure shown in FIGS. 15 and 16 may also be composed of the blue light chip 102 and the yellow fluorescent powder 103 packaged in silica gel on the surface of the blue light chip 102.

The LED package structure provided by the embodiments shown in FIGS. 13 to 14 greatly improves the luminous efficiency of each LED chip by a one-to-one correspondence between the optical cup and the LED chip. And the LED package structure shown in FIGS. 15 to 16 greatly reduces the manufacturing cost of LED packaging and improves packaging efficiency.

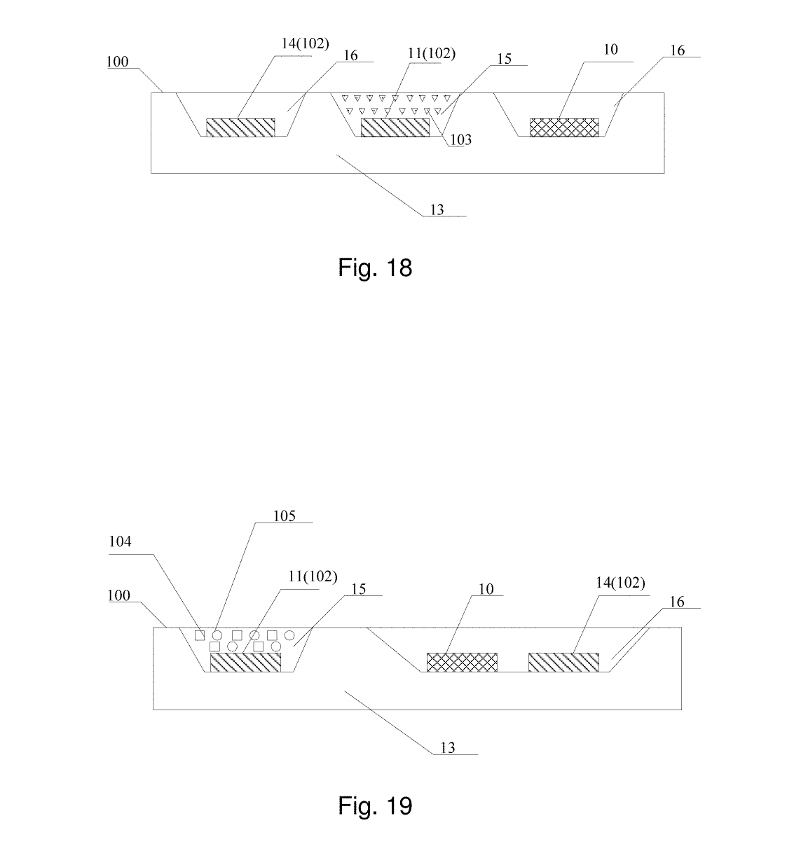

FIG. 17 is schematic structural diagram 13 of an LED package structure provided by an embodiment of the present application. FIG. 18 is schematic structural diagram 14 of an LED package structure provided by an embodiment of the present application.

In the embodiments shown in FIGS. 17 to 18, The first LED chip 14 may be a blue light chip 102 emitting blue light. The above-mentioned LED package holder 13 related to the LED package structure 100 may include three optical cups: one first optical cup 15, two second optical cups 16, respectively. The white-light LED structure 11 is packaged in the first optical cup 15, and the graphene LED chip 10 and the first LED chip 14 (i.e., the blue light chip 102) are arranged in one second optical cup 16, respectively and correspondingly. The positions of the above-mentioned first LED chip 14 and the graphene LED chip 10 can be arbitrarily interchanged to form the embodiments shown in FIGS. 17 and 18, as long as the white-light LED structure 11 is individually packaged in the first optical cup 15.

FIG. 19 is schematic structural diagram 15 of an LED package structure provided by an embodiment of the present application. FIG. 20 is schematic structural diagram 16 of an LED package structure provided by an embodiment of the present application. In the embodiments of FIGS. 19 to 20, the first LED chip 14 may be a blue light chip 102 emitting blue light, and the LED package holder 13 related to the above-mentioned LED package structure 100 may include two optical cups, namely a first optical cup 15 and a second optical cup 16, and the graphene LED chip 10 and the first LED chip 14 (i.e., the blue light chip 102) are arranged in one second optical cup 16 jointly. The positions of the above-mentioned first LED chip 14 and the graphene LED chip 10 in the one second optical cup 16 can be arbitrarily interchanged to form the embodiments shown in FIGS. 19 and 20, as long as the white-light LED structure 11 is individually packaged in the first optical cup 15.

In the embodiments shown in FIGS. 17 to 20, reference may also be made to FIG. 12 to describe the display principle of the complementary color area. Taking the complementary color area \textcircled{1} in FIG. 12 as an example, as for the display of \textcircled{1} area, point N (the blue light point) may be emitted separately by the blue light chip 102 (at which time the graphene LED chip 10 is turned off) and may also be emitted by the graphene LED chip 10 (at which time the blue chip 102 is turned off), or may further be emitted by the graphene LED chip 10 and the blue light chip 102 jointly when the two are turned on. Assuming that point N is emitted by the blue light chip 102, point A (red light point) is emitted by the graphene LED chip 10 and point O (white light point) is displayed by the white-light LED structure 11, then the triangle enclosed by points A, N and O can be displayed to cover the entire complementary color area \textcircled{1}; when other colors are displayed (e.g., assuming that the display of green is desired), the graphene LED chip 10 can adjust the display hue, the white-light LED structure 11 can adjust the saturation, and the blue light chip 102 is in the off state.

In the embodiments shown in FIGS. 17 to 20, the above-described white-light LED structure 11 may include a blue light chip 102 for emitting blue light and yellow fluorescent powder 103 packaged in silica gel on the surface of the blue light chip 102; or, it may include a blue light chip 102 for emitting blue light and green fluorescent powder 105 and red fluorescent powder 104 that are packaged in the silica gel on the surface of the blue light chip 102. It should be noted that, the white-light LED structure shown in FIGS. 17 and 18 is composed of the blue light chip 102 and yellow fluorescent powder 103 packaged in silica gel on the surface of the blue light chip 102, and the white-light LED structure shown in FIGS. 19 and 20 is composed of the blue light chip 102 and the green fluorescent powder 105 and red fluorescent powder 104 that are packaged in silica gel on the surface of the blue light chip 102, which only serve as examples, that is to say, the white-light LED structure shown in FIGS. 17 and 18 may also be composed of the blue light chip 102 and the green fluorescent powder 105 and red fluorescent powder 104 that are packaged in the silica gel on the surface of the blue light chip 102, and the white-light LED structure shown in FIGS. 19 and 20 may also be composed of the blue light chip 102 and the yellow fluorescent powder 103 packaged in silica gel on the surface of the blue light chip 102.

The LED package structure provided by the embodiments shown in FIGS. 17 to 18 greatly improves the luminous efficiency of each LED chip by a one-to-one correspondence between the optical cup and the LED chip. And the LED package structure shown in FIGS. 19 to 20 greatly reduces the manufacturing cost of LED packaging and improves packaging efficiency.

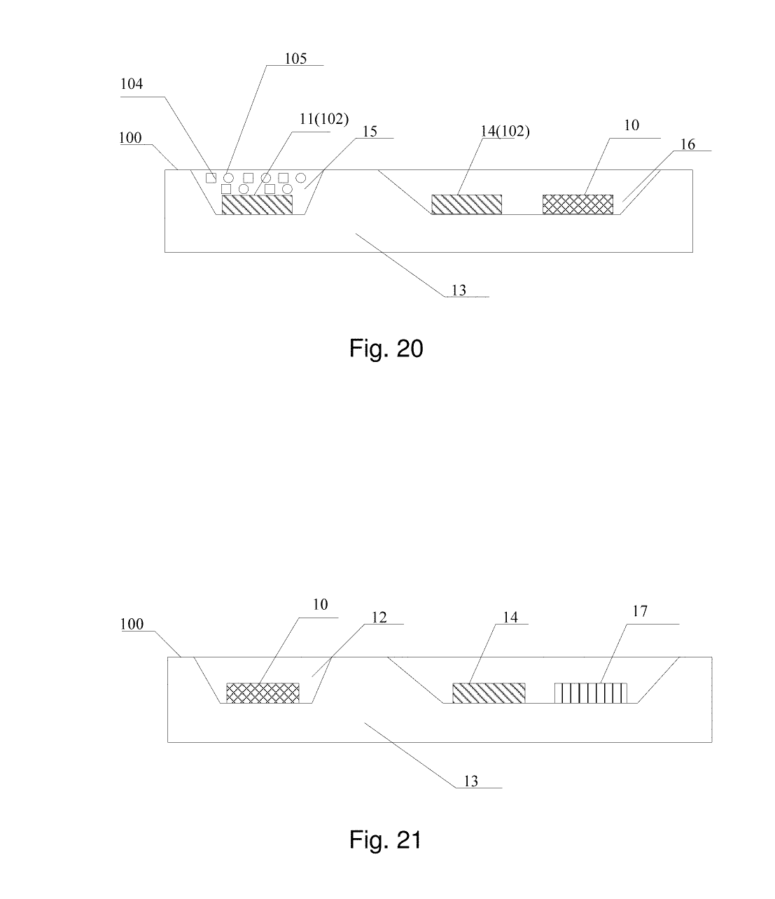

FIG. 21 is schematic structural diagram 17 of an LED package structure provided by an embodiment of the present application. As shown in FIG. 21, the LED package structure 100 includes: a graphene LED chip 10 having an adjustable emission wavelength, a first LED chip 14 and a second LED chip 17 for emitting primary color light, the colors of light emitted by the two being different, and an LED package holder 13 provided with an optical cup; where the graphene LED chip 10, the first LED chip 14 and the second LED chip 17 are packaged in the optical cup 12, and a plurality of adjustable wavelength points of the graphene LED chip 10 form a gamut display range together with the first wavelength point of the first LED chip 14 and the second wavelength point of the second LED chip 17, respectively.

The LED package structure 100 provided by the embodiments of the present application packages the above graphene LED chip 10, the first LED chip 14 and the second LED chip 17 for emitting primary color light, the colors of light emitted by the two being different, together into the optical cup 12 of the package holder. The first LED chip 14 has the fixed first wavelength point, i.e. the wavelength of the first LED chip 14 is fixed, and the second LED chip 17 also has the fixed second wavelength point, and the LED package holder 13 is made of highly reflective, illumination aging-resistant and highly malleable material, such as EMC material, which packages and protects the above-mentioned LED chips and other components, and the optical cup 12 on the package holder can improve the forward luminous efficiency. The number of the optical cups 12 in the LED package holder 13 may be one or more, and the number of the optical cups 12 is not limited by the embodiments of the present application. The number of the optical cups 12 shown in FIG. 21 takes 2 as an example, to which the application is not limited. The driving of the graphene LED chip 10, the first LED chip 14 and the second LED chip 17 is respectively and independently controlled.

Since the above graphene LED chip 10 has a plurality of adjustable wavelength points, and the first LED chip 14 and the second LED chip 17 have the respective fixed first and second wavelength points, each wavelength point of the above graphene LED chip 10 described above may form a display area with the first wavelength point and the second wavelength point, respectively, and the structure of the display area is a triangle. Thus, the plurality of adjustable wavelength points of the graphene LED chip 10 and the above first and second wavelength points form a plurality of triangles, and the area occupied by the plurality of triangles on the horseshoe chart is larger than that of the largest triangle in FIG. 1, and the reasons are as follows:

In the related art, the gamut range which the display device can display is the area occupied on the horseshoe chart by the largest triangle in FIG. 1, where the largest triangle in FIG. 1 is formed by the color mixing of red, green and blue, three vertices of the largest triangle are the red light point, blue light point and green light point; the LED package structure 100 of the present application includes two chips, namely the first LED chip 14 and the second LED chip 17, each of which has a fixed wavelength, and a graphene LED chip 10 with an adjustable wavelength, and the first LED chip 14 and the second LED chip 17 may correspond to two vertices of a triangle (the two vertices may correspond to any two vertices of the largest triangle of FIG. 1) in the horseshoe chart. In this way, only by adjusting a plurality of wavelength points of the graphene LED chip 10, can a plurality of triangles of different areas be enclosed, and when the wavelength points of the graphene LED chip 10 are adjusted, make sure that the areas of the plurality of enclosed triangles on the horseshoe chart are larger than the area of the largest triangle in FIG. 1.

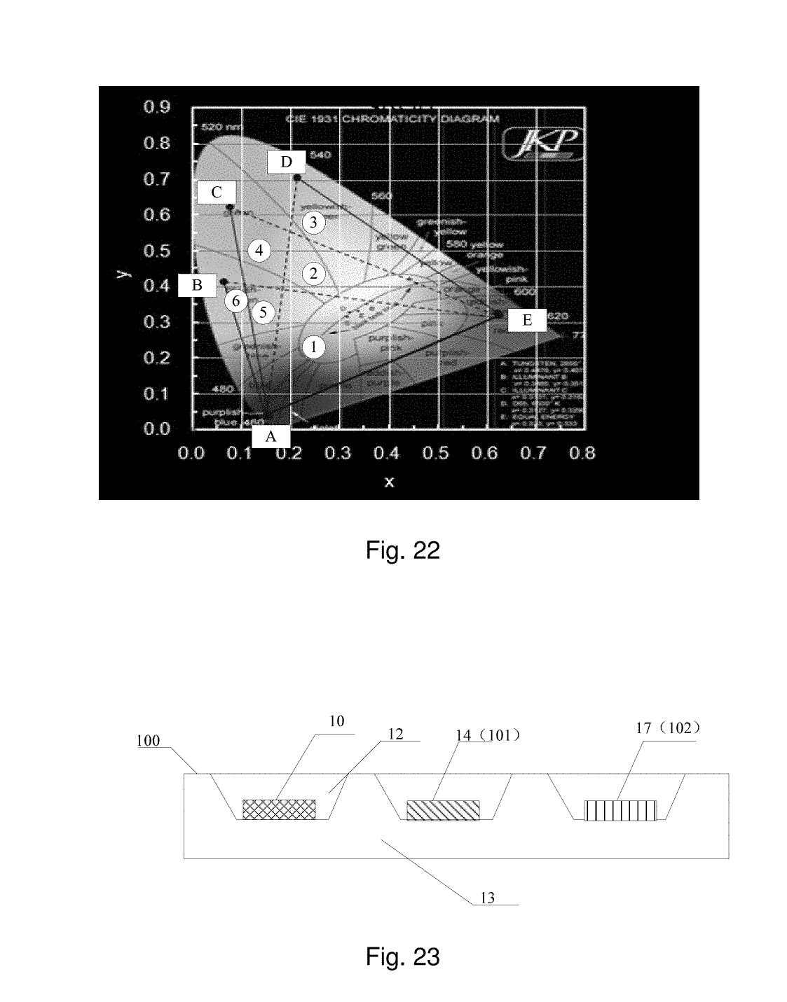

For example, reference is made to the schematic diagram 4 of a color display principle illustrated by FIG. 22, in FIG. 22, it is assumed that point A is the first wavelength point and point E is the second wavelength point; point B, point C, and point D are set to be several wavelength points of the graphene LED chip 10 in which the emission wavelength is adjustable. Now take setting three wavelength points by the graphene LED chip 10 as an example, a triangle is enclosed by each of the points B, C, D with the two points A and E, then a total of three triangles are enclosed in FIG. 22, and the area covered by the three triangles is the gamut display range that can be realized by the display device in the embodiment of the present application. Compare FIG. 22 with FIG. 1, the area of the triangle enclosed by points A, D and E has been equal to that of the largest triangle in FIG. 1, but there are nonoverlapping areas for triangles enclosed by points A, C, E and by points A, B and E, respectively, with the triangle enclosed by points A, D and E, then the gamut display range realized by the display apparatus is the sum of the area of the triangle enclosed by points A, D and E, and the areas of the two nonoverlapping areas. Thus the gamut display range of the display apparatus according to the embodiment of the present application is larger than that in the related art.

The LED package structure provided by the embodiment of the present application packages the above graphene LED chip 10 with adjustable emission wavelength, the first and the second LED chips 17 which are used for emitting primary color light, the colors of light emitted by the two being different, into the optical cup of the package holder, so as to obtain a plurality of adjustable wavelength points by adjusting the grid voltage of the graphene LED chip, so that the plurality of adjustable wavelength points may form a plurality of triangles with the first wavelength point of the first LED chip and the second wavelength point of the second LED chip, and it is ensured that the area occupied by the plurality of triangles, i.e., the gamut display range is larger than the that of the display device in the related art, that is, the LED package structure provided by the embodiment of the present application can greatly improve the gamut display range of the display apparatus.

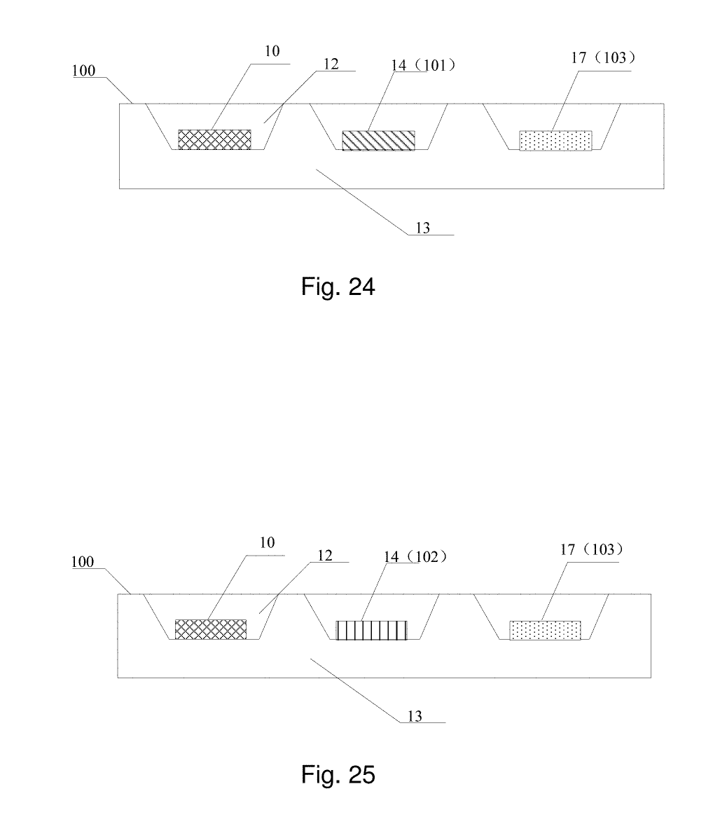

FIG. 23 is schematic structural diagram 18 of an LED package structure provided by an embodiment of the present application. FIG. 24 is schematic structural diagram 19 of an LED package structure provided by an embodiment of the present application. FIG. 25 is schematic structural diagram 20 of an LED package structure provided by an embodiment of the present application.

In the embodiments shown in FIGS. 23 to 25, the LED package holder 13 related to the LED package structure 100 may include three optical cups 12, and each of the graphene LED chip 10, the first LED chip 14 and the second LED chip 17 corresponds to one optical cup 12, respectively.

With reference to FIG. 23, the above-mentioned first LED chip 14 may be a red light chip 101 emitting red light, and the second LED chip 17 may be a blue light chip 102 emitting blue light. With reference to FIG. 24, the above-mentioned first LED chip 14 may be a red light chip 101 emitting red light, and the second LED chip 17 may be a green light chip 103 emitting green light. With reference to FIG. 25, the above-mentioned first LED chip 14 may be a blue light chip 102 emitting blue light, and the second LED chip 17 may be a green light chip 103 emitting green light. It should be noted that, in any one of FIGS. 23 to 25, the positions of the graphene LED chip 10, the first LED chip 14 and the second LED chip 17 may be arbitrarily interchanged in the package holder, for example, the first LED chip 14 of FIG. 23 may be arranged in the first optical cup 12 on the left, and the graphene LED chip 10 arranged in the optical cup 12 in the middle. Of course, they can be arranged in other interchanging manners as well, as long as one chip is packaged in one optical cup 12.

The LED package structure provided by the embodiments shown in FIGS. 23 to 25 greatly improves the luminous efficiency of each LED chip by the one-to-one correspondence between the optical cup and the LED chip.

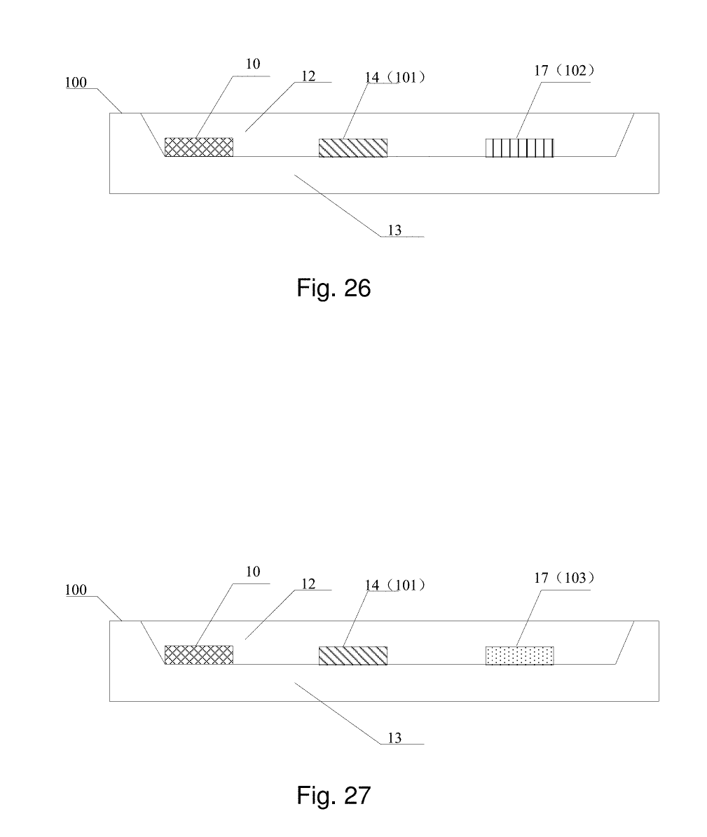

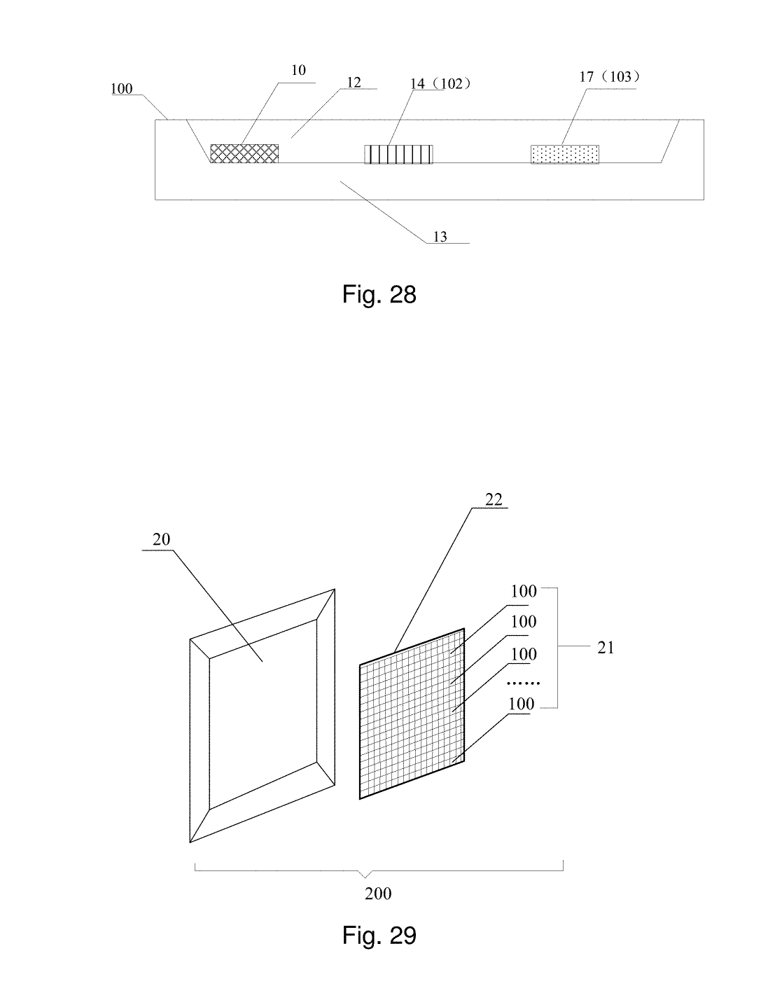

FIG. 26 is schematic structural diagram 21 of an LED package structure provided by an embodiment of the present application. FIG. 27 is schematic structural diagram 22 of an LED package structure provided by an embodiment of the present application. FIG. 28 is schematic structural diagram 23 of an LED package structure provided by an embodiment of the present application. In the embodiments shown in FIGS. 26 to 28, LED package holder 13 related to the above-mentioned LED package structure 100 may include one optical cup 12, and the graphene LED chip 10, the first LED chip 14, and the second LED chips 17 are packaged in the optical cup 12 jointly.

With reference to FIG. 26, the above-mentioned first LED chip 14 may be a red light chip 101 emitting red light, and the second LED chip 17 may be a blue light chip 102 emitting blue light. With reference to FIG. 27, the above-mentioned first LED chip 14 may be a red light chip 101 emitting red light, and the second LED chip 17 may be a green light chip 103 emitting green light. With reference to FIG. 28, the above-mentioned first LED chip 14 may be a blue light chip 102 emitting blue light, and the second LED chip 17 may be a green light chip 103 emitting green light. It should be noted that, in any one of FIGS. 26 to 28, the positions of the graphene LED chip 10, the first LED chip 14 and the second LED chip 17 may be arbitrarily interchanged in the optical cup 12, for example, the first LED chip 14 in FIG. 26 may be arranged in the optical cup 12 on the far left, and the graphene LED chip 10 arranged in the middle of the optical cup 12. Of course, they can be arranged in other interchanging manners as well, as long as the above three chips can be packaged in one optical cup 12.

The LED package structure shown in FIGS. 26 to 28 greatly improves the packaging efficiency of the LED packaging structure and reduces the packaging complexity and packaging cost by means of the fact that the graphene LED chip, the first LED chip and the second LED chip shares one optical cup.

FIG. 29 is a schematic structural diagram of a display apparatus provided by an embodiment of the present application. As shown in FIG. 29, the display apparatus 200 may include a housing 20 and a display panel 21, where the display panel 21 includes a plurality of LED package structures 100 involved in the embodiments described above; the plurality of LED package structures 100 are arranged in an array.

The display panel 21 is arranged in the housing 20 and the above LED package structure 100 is arranged on a printed circuit board (PCB) 22 of the display apparatus 200.

In the display apparatus 200, since an LED package structure including at least one graphene LED chip and a white-light LED structure is employed, a plurality of adjustable wavelength points can be obtained by adjusting the grid voltage of the graphene LED chip, so that the plurality of adjustable wavelength points may form a plurality of triangles with the white light point of the white-light LED structure, and it is ensured that the area occupied by the plurality of triangles, i.e. the gamut display range is larger than that of the display device in the related art, that is, the display apparatus provided by the embodiment of the present application greatly improves the gamut range that can be displayed.

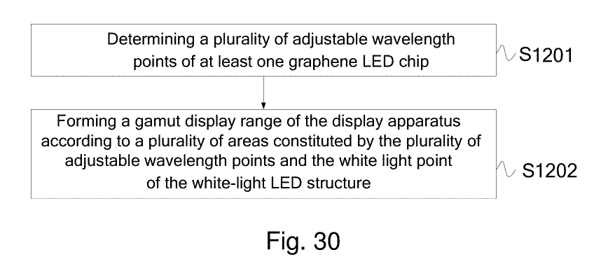

FIG. 30 is a flowchart of a method for color display of a display apparatus using an LED package structure provided by an embodiment of the present application. The display apparatus in the present embodiment may be the display apparatus shown in FIG. 29 described above, and the LED package structure shown in any one of the embodiments described above is used in the display apparatus. As shown in FIG. 30, the method may include:

S1201, determining a plurality of adjustable wavelength points of the at least one graphene LED chip.

S1202, forming a gamut display range of the display apparatus according to the plurality of adjustable wavelength points and the white light point of the white-light LED structure.

In this method, a plurality of adjustable wavelength points of at least one graphene LED chip can be obtained by applying voltages corresponding to a plurality of adjustable wavelength points. On the basis of the LED package structure according to any of the above embodiments, the at least one graphene LED chip used in the LED package structure has a first wavelength point and a second wavelength point among the plurality of adjustable wavelength points, which can form a display area with the white light point of the white-light LED structure, and the structure of the display area is a triangle. Thus, the plurality of adjustable wavelength points of the at least one graphene LED chip and the white light point of the white-light LED structure 11 may form a plurality of triangles. Each one of the plurality of triangles corresponds to a display area of the display apparatus. The plurality of display areas may form an entire gamut display range of the display apparatus.

In the method for color display of the display apparatus using the LED package structure provided in the embodiment of the present application, by determining a plurality of adjustable wavelength points of the at least one graphene LED chip and thus according to the plurality of areas formed by the plurality of adjustable wavelength points and the white light point of the white-light LED structure, the gamut display range of the display apparatus can be formed. Since the graphene LED chip has an adjustable wavelength point, a plurality of adjustable wavelength points can be obtained by adjusting the grid voltage of the at least one graphene LED chip, and the gamut display range formed according to the plurality of adjustable wavelength points and the white light point of the white-light LED structure can be improved, thereby gamut display range of the display apparatus can be greatly improved.

Finally, it should be noted that the above embodiments are merely illustrative of the technical solutions of the present application and are not intended to limit the solutions; while the present application has been described in detail with reference to the foregoing embodiments, it will be understood by those of ordinary skill in the art that, the technical solutions described in the foregoing embodiments can be modified, or some or all of the technical features can be equivalently replaced; and these modifications and substitutions do not cause the essence of the corresponding technical solutions depart from scope of the technical solutions of embodiments of the present application.

What is claimed is:

1. A light-emitting diode (LED) package structure, comprising: at least one graphene LED chip, a white-light LED structure, an LED package holder provided with an optical cup,
wherein the at least one graphene LED chip and the white-light LED structure are packaged in the optical cup, and a plurality of adjustable wavelength points of the at least one graphene LED chip together with a white light point of the white-light LED structure form a gamut display range.

2. The LED package structure according to claim 1, wherein the LED package structure further comprises a first LED chip for emitting primary color light, the first LED chip being packaged in the optical cup;
the plurality of adjustable wavelength points of the at least one graphene LED chip together with the white light point of the white-light LED structure forming the gamut display range comprises:
the gamut display range is formed by the plurality of adjustable wavelength points of the at least one graphene LED chip together with the white light point of the white-light LED structure and a wavelength point of the first LED chip, respectively.

3. The LED package structure according to claim 1, wherein a quantity of the graphene LED chip is one;
the graphene LED chip has a plurality of adjustable wavelength points in a time domain in sequence, wherein a time interval corresponding to adjacent adjustable wavelength points is within a preset time range.

4. The LED package structure according to claim 1, wherein a quantity of the graphene LED chip is more than one;
each graphene LED chip has at least one adjustable wavelength point in a time domain, and each graphene LED chip has a different adjustable wavelength point at a same moment.

5. The LED package structure according to claim 1, wherein the white-light LED structure comprises:
a blue-light LED chip, a red fluorescent material and a green fluorescent material.

6. The LED package structure according to claim 1, wherein the white-light LED structure comprises: a blue-light LED chip, a yellow fluorescent material.

7. The LED package structure according to claim 1, wherein the white-light LED structure comprises: an ultraviolet LED chip, a blue fluorescent material, a red fluorescent material, and a green fluorescent material.

8. The LED package structure according to claim 2, wherein the first LED chip is a red-light chip for emitting red light.

9. The LED package structure according to claim 2, wherein the first LED chip is a blue-light chip for emitting blue light.

10. The LED package structure according to claim 2, wherein the LED package holder comprises a first optical cup and at least one second optical cup, wherein,
the white-light LED structure is packaged in the first optical cup;
the at least one graphene LED chip and the first LED chip are packaged in the at least one second optical cup.

11. The LED package structure according to claim 10, wherein a quantity of the second optical cup is one,
the at least one graphene LED chip and the first LED chip are packaged in the one second optical cup jointly.

12. The LED package structure according to claim 10, wherein a quantity of the second optical cup is more than one;
the first LED chip is packaged in one second optical cup and the at least one graphene LED chip is packaged in other second optical cup.

13. The LED package structure according to claim 1, wherein the LED package holder comprises a first optical cup and at least one third optical cup, wherein,
the white-light LED structure is packaged in the first optical cup;
the at least one graphene LED chip is packaged in the at least one third optical cup.

14. The LED package structure according to claim 1, wherein the graphene LED chip uses a semi-reduced graphene oxide material, and an emission wavelength of the graphene LED chip is adjusted and controlled by structuring an in-plane grid structure of the chip and applying a voltage to a grid to adjust a Fermi level of the semi-reduced graphene oxide material.

15. A display apparatus, comprising: a housing and a display panel, wherein the display panel comprises a plurality of LED package structures according to claim 1, the plurality of LED package structures being arranged in an array;
wherein the display panel is arranged in the housing, and the LED package structures are arranged on a printed circuit board (PCB) of the display apparatus.

16. A method for color display of a display apparatus using a light-emitting diode (LED) package structure, wherein the LED package structure comprises the structure according to claim 1, the method comprises:
determining the plurality of adjustable wavelength points of the at least one graphene LED chip;
forming a gamut display range of the display apparatus according to a plurality of areas formed by the plurality of adjustable wavelength points and the white light point of the white-light LED structure.
